(19) United States
(12) Patent Application Publication
(10) Pub. No.: US 2023/0064637 A1
(43) Pub. Date: Mar. 2, 2023

(54) CLAMPED DUAL-CHANNEL SHOWERHEAD

(71) Applicant: Applied Materials, Inc., Santa Clara, CA (US)

(72) Inventors: Kiran Shyam Honnavar, Bangalore (IN); Srikantha Raju, Bangalore (IN); Gangadhar Sheelavant, Bengaluru (IN); Aniruddha Pal, San Jose, CA (US); Yao-Hung Yang, Santa Clara, CA (US); Basavaraja Shankarappa Kengunti, Bangalore (IN)

(73) Assignee: Applied Materials, Inc., Santa Clara, CA (US)

(21) Appl. No.: 17/893,430

(22) Filed: Aug. 23, 2022

Related U.S. Application Data
(60) Provisional application No. 63/236,998, filed on Aug. 25, 2021.

(51) Int. Cl. H01J 37/32; B05B 1/00; B05B 1/18; C23C 16/455; C23C 16/50

(52) U.S. Cl. CPC H01J 37/3244; B05B 1/005; B05B 1/185; C23C 16/45565; C23C 16/50; H01J 2237/332; H01J 37/32357

(57) ABSTRACT

Exemplary dual-channel showerheads may include an upper plate that defines a first plurality of apertures. The showerheads may include a base having a lower plate. The lower plate may define a second plurality of apertures and a third plurality of apertures. Each of the first plurality of apertures may be fluidly coupled with a respective one of the second plurality of apertures to define a fluid path extending from a top surface of the showerhead through a bottom surface of the showerhead. The base may define a gas inlet that is fluidly coupled with the third plurality of apertures. The base may be detachably coupled with the upper plate using one or more fastening mechanisms. The showerheads may include a compressible gasket positioned between the upper plate and the lower plate.

### CROSS-REFERENCE TO RELATED APPLICATIONS

This application claims the benefit of, and priority to U.S. Provisional Application Ser. No. 63/236,998, filed Aug. 25, 2021, which is hereby incorporated by reference in its entirety for all purposes.

### TECHNICAL FIELD

The present technology relates to semiconductor processes and equipment. More specifically, the present technology relates to processing system plasma components.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Dry etches produced in local plasmas formed within the substrate processing region can penetrate more constrained trenches and exhibit less deformation of delicate remaining structures. However, as integrated circuit technology continues to scale down in size, the equipment that delivers the precursors can impact the uniformity and quality of the precursors and plasma species used.

Thus, there is a need for improved system components that can be used in plasma environments effectively while providing suitable degradation profiles. These and other needs are addressed by the present technology.

### SUMMARY

Exemplary dual-channel showerheads may include an upper plate that defines a first plurality of apertures. The showerheads may include a base having a lower plate. The lower plate may define a second plurality of apertures and a third plurality of apertures. Each of the first plurality of apertures may be fluidly coupled with a respective one of the second plurality of apertures to define a fluid path extending from a top surface of the showerhead through a bottom surface of the showerhead. The base may define a gas inlet that is fluidly coupled with the third plurality of apertures. The base may be detachably coupled with the upper plate using one or more fastening mechanisms. The showerheads may include a compressible gasket that fluidly isolates the first plurality of apertures and the second plurality of apertures from the third plurality of apertures. The compressible gasket may be positioned between the upper plate and the lower plate.

In some embodiments, each of the third plurality of apertures may be fluidly isolated from the first plurality of apertures and the second plurality of apertures. The base may define a plenum that fluidly couples the gas inlet with each of the third plurality of apertures. The base may define a recursive flow path that fluidly couples the gas inlet with the plenum. The gasket may include a body characterized by a top surface and a bottom surface. One or both of the top surface and the bottom surface may include a plurality of spigots that protrude outward from the body of the gasket. Each of the plurality of spigots may be vertically aligned with a respective one of the first plurality of apertures. The gasket may include polytetrafluoroethylene (PTFE). One or both of a top surface of the gasket and a bottom surface of the gasket may include a plurality of spigots that protrude outward from a body of the gasket. The gasket may have a thickness that decreases as a radial distance from a center of the gasket increases. The lower plate may be detachably coupled with the base using one or more fasteners. The gasket may have a thickness that decreases as a radial distance from a center of the gasket increases.

Some embodiments of the present technology may encompass dual-channel showerheads. The showerheads may include an upper plate that defines a first plurality of apertures. The showerheads may include a base having a lower plate. The lower plate may define a second plurality of apertures and a third plurality of apertures. Each of the first plurality of apertures may be fluidly coupled with a respective one of the second plurality of apertures to define a fluid path extend from a top surface of the showerhead through a bottom surface of the showerhead. The base may define a gas inlet that is fluidly coupled with the third plurality of apertures. The base may be detachably coupled with the upper plate using one or more fastening mechanisms.

In some embodiments, the base may define a seat that receives the upper plate. An outer region of the seat may taper upward toward a periphery of the seat. A peripheral edge of a bottom surface of the upper plate may be tapered. A degree of taper of the outer region of the seat may match a degree of taper of the peripheral edge of the bottom surface of the seat. A bottom surface of the upper plate may include a plurality of spigots that extend downward from the bottom surface. Each of the plurality of spigots may define at least a portion of a respective one of the first plurality of apertures. The showerheads may include a plurality of seals. Each of the plurality of seals may be positioned at an interface between a bottom end of a respective one of the plurality of spigots and a top surface of the lower plate. A bottom surface of the upper plate may include a plurality of spigots that extend downward from the bottom surface. Each of the plurality of spigots may define at least a portion of a respective one of the first plurality of apertures. A top surface of the lower plate may include a plurality of receptor cups extending upward from the top surface. Each of the plurality of receptor cups may receive a respective one of the plurality of spigots. Each of the first plurality of apertures and each of the second plurality of apertures may be generally cylindrical. An inner wall of each of the third plurality of apertures may taper inward to a choke point disposed within a medial portion of the respective aperture. The base may include a heating coil extending at least partially about a circumference of the base.

Some embodiments of the present technology may encompass methods of processing a substrate. The methods may include flowing a plasma excited species into a processing chamber through a first plurality of apertures formed in an upper plate of a showerhead and a second plurality of apertures formed in a lower plate of the showerhead. The methods may include flowing a precursor into the processing chamber through a third plurality of apertures formed in the lower plate via a gas inlet formed in a base of the showerhead. The upper plate may be detachably coupled with the base using one or more fastening mechanisms. The methods may include removing an amount of material from a substrate positioned within the processing chamber.

In some embodiments, the showerhead may include a compressible gasket positioned between the upper plate and the lower plate. Flowing the precursor may include introducing the precursor into a plenum that is fluidly coupled with each of the third plurality of apertures via a recursive flow path that extends between the gas inlet and the plenum.

Such technology may provide numerous benefits over conventional systems and techniques. For example, the upper plate and/or lower plate of the dual-channel showerhead may be removably coupled with a base of the dual-channel showerhead to facilitate better cleaning of the dual-channel showerhead. Additionally, multiple precursors may be delivered through the assembly while being maintained fluidly isolated from one another. For example, gaskets, seals, and/or interlock mechanisms may be used to fluidly isolate the two fluid paths from one another. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing tool.

FIGS. 2A-2C show schematic cross-sectional views of an exemplary processing chamber.

FIGS. 3A-3E show schematic views of exemplary showerhead configurations according to the disclosed technology.

FIG. 4 shows a schematic view of an exemplary showerhead configuration according to the disclosed technology.

FIG. 5 shows a schematic view of an exemplary showerhead configuration according to the disclosed technology.

FIG. 6 shows a schematic view of an exemplary showerhead configuration according to the disclosed technology.

FIG. 7 shows a schematic view of an exemplary showerhead configuration according to the disclosed technology.

FIGS. 8A and 8B show schematic views of exemplary showerhead configurations according to the disclosed technology.

FIG. 9 shows a schematic view of an exemplary showerhead configuration according to the disclosed technology.

FIG. 10 is a flowchart of an exemplary method of semiconductor processing according to some embodiments of the present technology.

In the appended figures, similar components and/or features may have the same numerical reference label. Further, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION

Dual-channel showerheads and other gas distribution systems are often used to provide multiple fluid flow paths to deliver multiple process gases to a processing region of a semiconductor processing chamber for deposition and/or etching operations. Conventional dual-channel showerheads include a body that includes upper and lower plates that are fused together, such as by brazing, electron beam welding, and/or other techniques. However, these dual-channel showerheads may be difficult to clean, as the small size of the apertures may make it difficult for cleaning solutions to flow into the interior of the dual-channel showerhead. As a result, residue may collect within the interior of the showerhead. This residue may alter the flow conductance through the showerhead and may cause residue particles to drop on the wafer. Additionally, process gases may react with the residue. Such issues may lead to non-uniformity issues and on wafer defects.

The present technology overcomes these challenges by incorporating upper and/or lower plates that are removably coupled with the base of the dual-channel showerhead. This enables the showerhead to be opened up to expose the interior of the various showerhead components for cleaning. By facilitating better cleaning of the showerhead, embodiments described herein may provide better uniformity of processing operations and may prevent fall on defects and the reaction of process gases with deposits of any residue within the showerhead. Additionally, the showerheads may include gaskets, seals, and/or interlocking components that help fluidly isolate flow paths for two different gases, which enables the dual-channel showerhead to deliver two different process gases to a process region of a processing chamber without the two gases mixing until reaching the processing region.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include pedestals according to embodiments of the present technology before additional variations and adjustments to this system according to embodiments of the present technology are described.

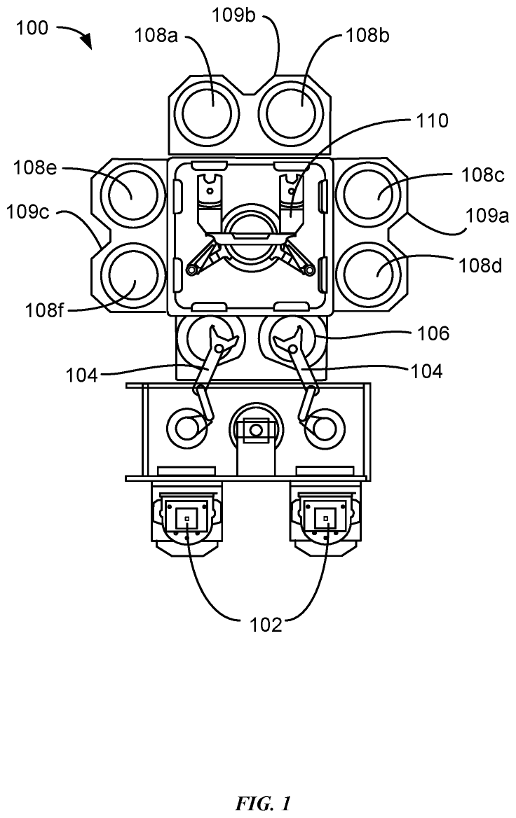

FIG. 1 shows a top plan view of one embodiment of a processing tool 100 of deposition, etching, baking, and/or curing chambers according to disclosed embodiments. In the figure, a pair of FOUPs (front opening unified pods) 102 supply substrates (e.g., various specified diameter semiconductor wafers) that may be received by robotic arms 104 and placed into a low-pressure holding area 106 before being placed into one of the substrate processing sections 108a-f of the tandem process chambers 109a-c. A second robotic arm 110 may be used to transport the substrates from the holding area 106 to the processing chambers 108a-f and back.

The substrate processing sections 108a-f of the tandem process chambers 109a-c may include one or more system components for depositing, annealing, curing and/or etching substrates or films thereon. Exemplary films may be flowable dielectrics, but many types of films may be formed or processed with the processing tool. In one configuration, two pairs of the tandem processing sections of the processing chamber (e.g., 108c-d and 108e-f) may be used to deposit the dielectric material on the substrate, and the third pair of tandem processing sections (e.g., 108a-b) may be used to anneal the deposited dielectric. In another configuration, the two pairs of the tandem processing sections of processing chambers (e.g., 108c-d and 108e-f) may be configured to both deposit and anneal a dielectric film on the substrate, while the third pair of tandem processing sections (e.g., 108a-b) may be used for UV or E-beam curing of the deposited film. In still another configuration, all three pairs of tandem processing sections (e.g., 108a-f) may be configured to deposit and cure a dielectric film on the substrate or etch features into a deposited film.

In yet another configuration, two pairs of tandem processing sections (e.g., 108c-d and 108e-f) may be used for both deposition and UV or E-beam curing of the dielectric, while a third pair of tandem processing sections (e.g. 108a-b) may be used for annealing the dielectric film. In addition, one or more of the tandem processing sections 108a-f may be configured as a treatment chamber, and may be a wet or dry treatment chamber. These process chambers may include heating the dielectric film in an atmosphere that includes moisture. Thus, embodiments of system 100 may include wet treatment tandem processing sections 108a-b and anneal tandem processing sections 108c-d to perform both wet and dry anneals on the deposited dielectric film. It will be appreciated that additional configurations of deposition, annealing, and curing chambers for dielectric films are contemplated by system 100.

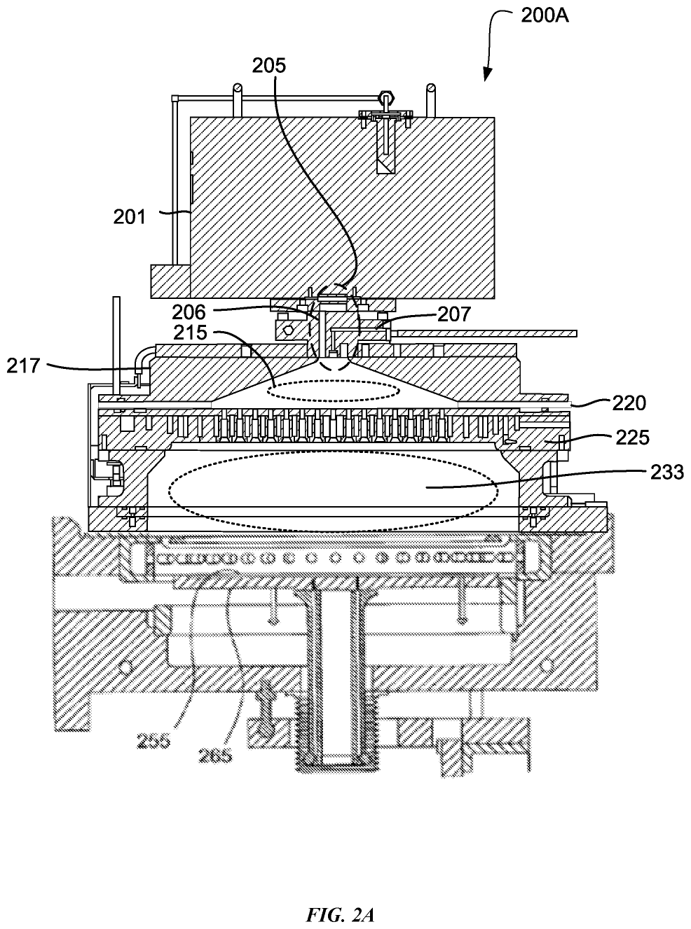

FIG. 2A is a cross-sectional view of an exemplary process chamber section 200 with partitioned plasma generation regions within the processing chambers. During film deposition (e.g., silicon oxide, silicon nitride, silicon oxynitride, or silicon oxycarbide), a process gas may be flowed into the first plasma region 215 through a gas inlet assembly 205. A remote plasma system (RPS) 201 may process a gas which then travels through gas inlet assembly 205. Two distinct gas supply channels are visible within the gas inlet assembly 205. A first channel 206 carries a gas that passes through the remote plasma system (RPS) 201, while a second channel 207 bypasses the RPS 201. The first channel 206 may be used for the process gas and the second channel 207 may be used for a treatment gas in disclosed embodiments. The process gas may be excited prior to entering the first plasma region 215 within a remote plasma system (RPS) 201. A lid 212, a showerhead 225, and a substrate support 265, having a substrate 255 disposed thereon, are shown according to disclosed embodiments. The lid 212 may be pyramidal, conical, or of another similar structure with a narrow top portion expanding to a wide bottom portion. Additional geometries of the lid 212 may also be used. The lid (or conductive top portion) 212 and showerhead 225 are shown with an insulating ring 220 in between, which allows an AC potential to be applied to the lid 212 relative to showerhead 225. The insulating ring 220 may be positioned between the lid 212 and the showerhead 225 enabling a capacitively coupled plasma (CCP) to be formed in the first plasma region. A baffle (not shown) may additionally be located in the first plasma region 215 to affect the flow of fluid into the region through gas inlet assembly 205.

A fluid, such as a precursor, for example a silicon-containing precursor, may be flowed into the processing region 233 by embodiments of the showerhead described herein. Excited species derived from the process gas in the plasma region 215 may travel through apertures in the showerhead 225 and react with the precursor flowing into the processing region 233 from the showerhead. Little or no plasma may be present in the processing region 233. Excited derivatives of the process gas and the precursor may combine in the region above the substrate and, on occasion, on the substrate to form a film on the substrate that may be flowable in disclosed applications. For flowable films, as the film grows, more recently added material may possess a higher mobility than underlying material. Mobility may decrease as organic content is reduced by evaporation. Gaps may be filled by the flowable film using this technique without leaving traditional densities of organic content within the film after deposition is completed. A curing step may still be used to further reduce or remove the organic content from a deposited film.

Exciting the process gas in the first plasma region 215 directly, exciting the process gas in the RPS, or both, may provide several benefits. The concentration of the excited species derived from the process gas may be increased within the processing region 233 due to the plasma in the first plasma region 215. This increase may result from the location of the plasma in the first plasma region 215. The processing region 233 may be located closer to the first plasma region 215 than the remote plasma system (RPS) 201, leaving less time for the excited species to leave excited states through collisions with other gas molecules, walls of the chamber, and surfaces of the showerhead.

The uniformity of the concentration of the excited species derived from the process gas may also be increased within the processing region 233. This may result from the shape of the first plasma region 215, which may be more similar to the shape of the processing region 233. Excited species created in the remote plasma system (RPS) 201 may travel greater distances in order to pass through apertures near the edges of the showerhead 225 relative to species that pass through apertures near the center of the showerhead 225. The greater distance may result in a reduced excitation of the excited species and, for example, may result in a slower growth rate near the edge of a substrate. Exciting the process gas in the first plasma region 215 may mitigate this variation.

The processing gas may be excited in the RPS 201 and may be passed through the showerhead 225 to the processing region 233 in the excited state. Alternatively, power may be applied to the first processing region to either excite a plasma gas or enhance an already exited process gas from the RPS. While a plasma may be generated in the processing region 233, a plasma may alternatively not be generated in the processing region. In one example, the only excitation of the processing gas or precursors may be from exciting the processing gas in the RPS 201 to react with the precursors in the processing region 233.

The processing chamber and this discussed tool are more fully described in patent application Ser. No. 12/210,940 filed on Sep. 15, 2008, and patent application Ser. No. 12/210,982 filed on Sep. 15, 2008, which are incorporated herein by reference to the extent not inconsistent with the claimed aspects and description herein.

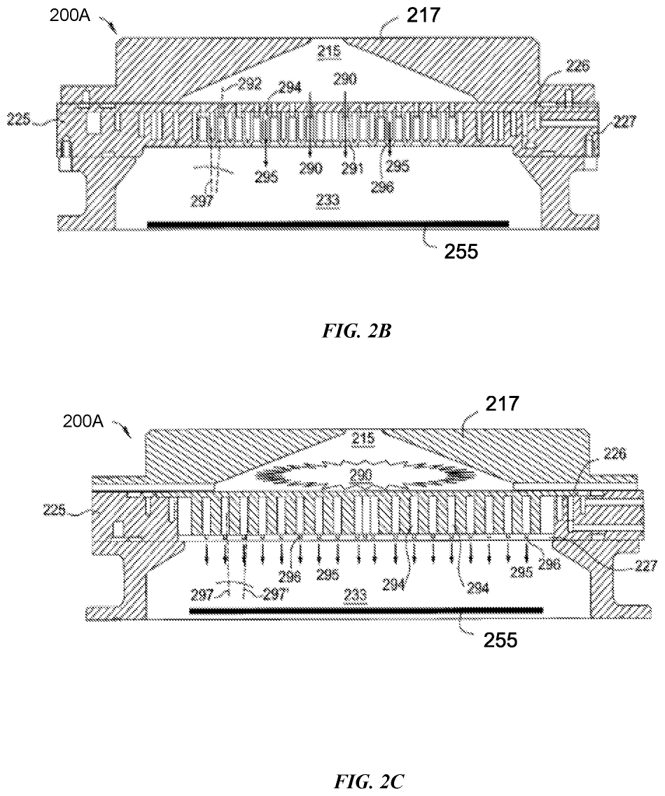

FIGS. 2B-2C are side schematic views of one embodiment of the precursor flow processes in the processing chambers and the gas distribution assemblies described herein. The gas distribution assemblies for use in the processing chamber section 200 may be referred to as dual-channel showerheads (DCSH) or triple channel showerheads (TCSH) and are detailed in the embodiments described in FIGS. 3A-3E, 4, 5, 6, 7, 8A, 8B, and 9 herein. The dual or triple channel showerhead may allow for flowable deposition of a dielectric material, and separation of precursor and processing fluids during operation. The showerhead may alternatively be utilized for etching processes that allow for separation of etchants outside of the reaction zone to provide limited interaction with chamber components.

Precursors may be introduced into the distribution zone by first being introduced into an internal showerhead volume 294 defined in the showerhead 225 by a first manifold 226, or upper plate, and second manifold 227, or lower plate. The manifolds may be perforated plates that define a plurality of apertures. The precursors in the internal showerhead volume 294 may flow 295 into the processing region 233 via apertures 296 formed in the lower plate. This flow path may be isolated from the rest of the process gases in the chamber, and may provide for the precursors to be in an unreacted or substantially unreacted state until entry into the processing region 233 defined between the substrate 255 and a bottom of the lower plate 227. Once in the processing region 233, the precursor may react with a processing gas. The precursor may be introduced into the internal showerhead volume 294 defined in the showerhead 225 through a side channel formed in the showerhead, such as gas inlets 322, 422, 522, 622, 722, 822, 922 as shown in the showerhead embodiments herein. The process gas may be in a plasma state including radicals from the RPS unit or from a plasma generated in the first plasma region. Additionally, a plasma may be generated in the processing region.

Processing gases may be provided into the first plasma region 215, or upper volume, defined by the faceplate 217 and the top of the showerhead 225. The processing gas may be plasma excited in the first plasma region 215 to produce process gas plasma and radicals. Alternatively, the processing gas may already be in a plasma state after passing through a remote plasma system prior to introduction to the first plasma processing region 215 defined by the faceplate 217 and the top of the showerhead 225.

The processing gas including plasma and radicals may then be delivered to the processing region 233 for reaction with the precursors though channels, such as channels 290, formed through the apertures in the showerhead plates or manifolds. The processing gasses passing though the channels may be fluidly isolated from the internal showerhead volume 294 and may not react with the precursors passing through the internal showerhead volume 294 as both the processing gas and the precursors pass through the showerhead 225. Once in the processing volume, the processing gas and precursors may mix and react.

In addition to the process gas and a dielectric material precursor, there may be other gases introduced at varied times for varied purposes. A treatment gas may be introduced to remove unwanted species from the chamber walls, the substrate, the deposited film and/or the film during deposition. A treatment gas may be excited in a plasma and then used to reduce or remove residual content inside the chamber. In other disclosed embodiments the treatment gas may be used without a plasma. When the treatment gas includes water vapor, the delivery may be achieved using a mass flow meter (MFM), an injection valve, or by commercially available water vapor generators. The treatment gas may be introduced from the first processing region, either through the RPS unit or bypassing the RPS unit, and may further be excited in the first plasma region.

The axis 292 of the opening of apertures 291 and the axis 297 of the opening of apertures 296 may be parallel or substantially parallel to one another. Alternatively, the axis 292 and axis 297 may be angled from each other, such as from about 1° to about 80°, for example, from about 1° to about 30°. Alternatively, each of the respective axes 292 may be angled from each other, such as from about 1° to about 80°, for example, from about 1° to about 30°, and each of the respective axis 297 may be angled from each other, such as from about 1° to about 80°, for example, from about 1° to about 30°.

The respective openings may be angled, such as shown for aperture 291 in FIG. 2B, with the opening having an angle from about 1° to about 80°, such as from about 1° to about 30°. The axis 292 of the opening of apertures 291 and the axis 297 of the opening of apertures 296 may be perpendicular or substantially perpendicular to the surface of the substrate 255. Alternatively, the axis 292 and axis 297 may be angled from the substrate surface, such as less than about 5°.

FIG. 2C illustrates a partial schematic view of the processing chamber 200 and showerhead 225 illustrating the precursor flow 295 from the internal volume 294 through apertures 296 into the processing region 233. The figure also illustrates an alternative embodiment showing axis 297 and 297′ of two apertures 296 being angled from one another.

FIG. 3A illustrates an upper perspective view of a dual-channel showerhead 300. FIG. 3A may include one or more components discussed above with regard to FIG. 2A, and may illustrate further details relating to that chamber. The dual-channel showerhead 300 may be used to perform semiconductor processing operations including deposition of stacks of dielectric materials and/or etching operations as previously described. Dual-channel showerhead 300 may be used in semiconductor processing chambers, such as chamber 200 described above, and may not include all of the components, such as additional lid stack components previously described, which are understood to be incorporated in some embodiments of dual-channel showerhead 300. In usage, the a dual-channel showerhead 300 may have a substantially horizontal orientation such that an axis of the gas apertures formed therethrough may be perpendicular or substantially perpendicular to the plane of the substrate support (see substrate support 265 in FIG. 2A). FIG. 3B illustrates an exploded perspective view of the dual-channel showerhead 300. FIG. 3C is a cross-sectional side elevation view of the dual-channel showerhead 300. FIGS. 3D and 3E illustrate cross-sectional top plan views of gas channel configurations of the dual-channel showerhead 300.

Referring to FIGS. 3A-3E, the dual-channel showerhead 300 generally includes a base 335 having an annular body 340, an upper plate 320, and a lower plate 325. In some embodiments, the lower plate 325 may be formed integrally with the annular body 340, while in other embodiments the lower plate 325 may be a separate component. The annular body 340 may be a ring which has an inner annular wall 301 located at an inner diameter, an outer annular wall 305 located at an outer diameter, an upper surface 315, and a lower surface 310. The upper surface 315 and lower surface 310 define the thickness of the annular body 340. A conduit or annular temperature channel or recess may be defined within the annular body 340 and may be configured to receive a cooling fluid or a heating element that may be used to maintain or regulate the temperature of the annular body. For example, as illustrated in FIG. 3C, a conduit may be formed in the bottom surface 310 and a heating element 355 may be disposed therein. The heating element 355 and/or cooling channel may extend about all or substantially all of the annular body 340.

One or more recesses and/or channels may be formed in or defined by the annular body as shown in disclosed embodiments including that illustrated in FIG. 3D. The annular body may include an upper recess 303 formed in the upper surface. The upper recess 303 may be a upper recess formed in the annular body 340. As shown in FIGS. 3B and 3C, a first fluid channel 306 may be defined in the upper surface 315, and may be located in the annular body radially inward of the upper recess 303. The first fluid channel 306 may be annular in shape and be formed the entire distance around the annular body 340. In disclosed embodiments, a bottom portion of the upper recess 303 intersects an outer wall of the first fluid channel 306. As best illustrated in FIGS. 3D and 3E, a number of ports 312 may be defined in an inner wall of the first fluid channel, also the inner annular wall 301 of the annular body 340. The ports 312 may provide access between the first fluid channel and the internal volume defined between the upper plate 320 and lower plate 325. The ports 312 may be defined around the circumference of the channel 306 at specific intervals, and may facilitate distribution across the entire region of the volume defined between the upper and lower plates, which may form a plenum 347. The intervals of spacing between the ports 312 may be constant, or may be varied in different locations to affect the flow of fluid into the volume. In some embodiments, a length of each port 312 may be constant, such as shown in FIG. 3D. In other embodiments, one or more of the ports 312a may extend a greater distance into an interior of the plenum 347. For example, as illustrated in FIG. 3E four (of eight) equally spaced apart ports 312a may extend further into a center of the plenum 347 (such as beyond 30% of the radius of the channel 306, beyond or about 40% of the radius, beyond or about 50% of the radius, beyond or about 60% of the radius, beyond or about 70% of the radius, beyond or about 80% of the radius, or more) than the remaining ports 312. It will be appreciated that any number and/or configuration of ports may be utilized to achieve a desired gas distribution within the plenum 347. The inner and outer walls, radially, of the first fluid channel 306 may be of similar or dissimilar height. For example, the inner wall may be formed higher than the outer wall to affect the distribution of fluids in the first fluid channel to avoid or substantially avoid the flow of fluid over the inner wall of the first fluid channel.

Again referring to FIGS. 3B and 3C, a second fluid channel 308 may be defined in the upper surface 315 that is located in the annular body radially outward of the first fluid channel 306. Second fluid channel 308 may be an annular shape and be located radially outward from and concentric with first fluid channel 306. The second fluid channel 308 may also be located radially outward of the first upper recess 303. A second plurality of ports 314 may be defined in the portion of the annular body 340 defining the outer wall of the first fluid channel 306 and the inner wall of the second fluid channel 308. The second plurality of ports 314 may be located at intervals of a pre-defined distance around the channel to provide fluid access to the first fluid channel 306 at several locations about the second fluid channel 308. In operation, a precursor may be flowed from outside the process chamber to a delivery channel or gas inlet 322 located in the side of the annular body 340. The fluid may flow into the second fluid channel 308, through the second plurality of ports 314 into the first fluid channel 306, through the first plurality of ports 312 into the plenum 347 defined between the upper and lower plates, and through third apertures 375 located in the lower plate. As such, a fluid provided in such a fashion can be isolated or substantially isolated from any fluid delivered into the first plasma region through first apertures 360 (formed in the upper plate 320) and second apertures 365 (formed in the lower plate 325) until the fluids separately exit the lower plate 325. The fluid channels and fluid ports may together define a recursive flow path that that fluidly couples the gas inlet 322 with the plenum 347 to uniformly distribute the fluid within the plenum 347.

The upper plate 320 may be a disk-shaped body, and may be coupled with the annular body 340 at the first upper recess 303 or other seat. The upper plate 320 may thus cover the first fluid channel 306 to prevent or substantially prevent fluid flow from the top of the first fluid channel 306. The upper plate may have a diameter selected to mate with the diameter of the upper recess 303, and the upper plate may include a plurality of first apertures 360 formed therethrough. As seen in FIG. 3A, the first apertures 360 may be arranged in a polygonal pattern on the upper plate 320, such that an imaginary line drawn through the centers of the outermost first apertures 360 define or substantially define a polygonal figure, which may be for example, a six-sided polygon.

The pattern may also feature an array of staggered rows from about 5 to about 60 rows, such as from about 15 to about 25 rows of first apertures 360. Each row may have, along the y-axis, from about 5 to about 20 first apertures 360, with each row being spaced between about 0.4 and about 0.7 inches apart. Each first aperture 360 in a row may be displaced along the x-axis from a prior aperture between about 0.4 and about 0.8 inches from each respective diameter. The first apertures 360 may be staggered along the x-axis from an aperture in another row by between about 0.2 and about 0.4 inches from each respective diameter. The first apertures 360 may be equally spaced from one another in each row.

The upper plate 320 may be removably fastened to the annular body 340 of base 335. For example, a peripheral edge of the upper plate 320 may include screws, bolts, clamp, and/or other fastening mechanisms 380. The fastening mechanism 380 may extend through a thickness of the upper plate 320 and into at least a portion of the annular body 340. For example, an edge region of the upper plate 320 may be thinner than a medial region of the upper plate 320 such that top surfaces of the fastening mechanisms 380 may be positioned below a top surface of the medial region of the upper plate 320. By using fastening mechanisms 380, the upper plate 320 may be removably secured to the base 335, which may facilitate better cleaning of the dual-channel showerhead 300 as cleaning solutions may be directly applied to the interior surfaces of the dual-channel showerhead 300 once the upper plate 320 is removed.

The lower plate 325 may have a disk-shaped body having a number of second apertures 365 and third apertures 375 formed therethrough, as especially seen in FIG. 3C. The lower plate 325 may have multiple thicknesses, with the thickness of defined portions greater than the central thickness of the upper plate 320, and in disclosed embodiments at least about twice the thickness of the upper plate 320. The lower plate 325 may also have a diameter that mates with the diameter of the inner annular wall 301 of the annular body 340 at the first lower recess 302. The lower plate 325 may be formed separately from the annular body 340, and may be removably mated to the annular body 340 using one or more fastening mechanisms. In other embodiments, the lower plate 325 may be permanently coupled with the annular body 340, such as by brazing the components together. In other embodiments, the lower plate 325 may be formed integrally with the annular body 340. As mentioned, the lower plate 325 may have multiple thicknesses, and for example, a first thickness of the plate may be the thickness through which the third apertures 375 extend. A second thickness greater than the first may be a thickness of the plate around the second apertures 365. For example, the second apertures 365 may be defined by the lower plate 325 as cylindrical bodies or spigots 327 extending up toward the upper plate 320. In this way, channels may be formed between the first and second apertures that are fluidly isolated from one another. Additionally, the plenum 347 formed between the upper and lower plates may be fluidly isolated from the channels formed between the first and second apertures. As such, a fluid flowing through the first apertures 360 will flow through the second apertures 365 and a fluid within the plenum 347 between the plates will flow through the third apertures 375, and the fluids will be fluidly isolated from one another until they exit the lower plate 325 through either the second or third apertures. This separation may provide numerous benefits including preventing a radical precursor from contacting a second precursor prior to reaching a reaction zone. By preventing the interaction of the gases, deposition within the chamber may be minimized prior to the processing region in which deposition is desired.

The second apertures 365 may be arranged in a pattern that aligns with the pattern of the first apertures 360 as described above. In one embodiment, when the upper plate 320 and lower plate 325 are positioned one on top of the other, the axes of the first apertures 360 and second apertures 365 align. In disclosed embodiments, the upper and lower plates may be coupled with one another or directly bonded together. Under either scenario, the coupling of the plates may occur such that the first and second apertures are aligned to form a channel through the upper and lower plates. The plurality of first apertures 360 and the plurality of second apertures 365 may have their respective axes parallel or substantially parallel to each other, for example, the apertures 360, 365 may be concentric. Alternatively, the plurality of first apertures 360 and the plurality of second apertures 365 may have the respective axis disposed at an angle from about 1° to about 30° from one another. At the center of the lower plate 325 there may be no second aperture 365.

As stated previously, the dual-channel showerhead 300 generally consists of the annular body 340, the upper plate 320, and the lower plate 325. The lower plate 325 may be positioned within the first lower recess 303 with the raised cylindrical bodies or spigots 327 facing toward the bottom surface of the upper plate 320, as shown in FIG. 3B. The lower plate 325 may then be positioned in the first lower recess 304 and rotatably oriented so that the axes of the first and second apertures 360, 365 may be aligned.

The plurality of second apertures 365 and the plurality of third apertures 375 may form alternating staggered rows. The third apertures 375 may be arranged in between at least two of the second apertures 365 of the lower plate 325. Between each second aperture 365 there may be a third aperture 375, which is evenly spaced between the two second apertures 365. There may also be a number of third apertures 375 positioned around the center of the lower plate 325 in a hexagonal pattern, such as for example six third apertures, or a number of third apertures 375 forming another geometric shape. There may be no third aperture 375 formed in the center of the lower plate 325. There may also be no third apertures 375 positioned between the perimeter second apertures 365 which form the vertices of the polygonal pattern of second apertures. Alternatively there may be third apertures 375 located between the perimeter second apertures 365, and there may also be additional third apertures 375 located outwardly from the perimeter second apertures 365 forming the outermost ring of apertures as shown, for example, in FIG. 3C.

Alternatively, the arrangement of the first and second apertures may make any other geometrical pattern, and may be distributed as rings of apertures located concentrically outward from each other and based on a centrally located position on the plate. As one example, and without limiting the scope of the technology, FIG. 3A shows a pattern formed by the apertures that includes concentric hexagonal rings extending outwardly from the center. Each outwardly located ring may have the same number, more, or less apertures than the preceding ring located inwardly. In one example, each concentric ring may have an additional number of apertures based on the geometric shape of each ring. In the example of a six-sided polygon, each ring moving outwardly may have six apertures more than the ring located directly inward, with the first internal ring having six apertures. With a first ring of apertures located nearest to the center of the upper and lower plates, the upper and lower plates may have more than two rings, and depending on the geometric pattern of apertures used, may have between about one and about fifty rings of apertures. Alternatively, the plates may have between about two and about forty rings, or up to about thirty rings, about twenty rings, about fifteen rings, about twelve rings, about ten rings, about nine rings, about eight rings, about seven rings, about six rings, etc. or less. In one example, as shown in FIG. 3A, there may be nine hexagonal rings on the exemplary upper plate.

The concentric rings of apertures may also not have one of the concentric rings of apertures, or may have one of the rings of apertures extending outward removed from between other rings. For example with reference to FIG. 3A, where an exemplary nine hexagonal rings are on the plate, the plate may instead have eight rings, but it may be ring four that is removed.

In such an example, channels may not be formed where the fourth ring would otherwise be located which may redistribute the gas flow of a fluid being passed through the apertures. The rings may still also have certain apertures removed from the geometric pattern. For example again with reference to FIG. 3A, a tenth hexagonal ring of apertures may be formed on the plate shown as the outermost ring. However, the ring may not include apertures that would form the vertices of the hexagonal pattern, or other apertures within the ring.

The first, second, and third apertures 360, 365, 375 may all be adapted to allow the passage of fluid therethrough. The first and second apertures 360, 365 may have cylindrical shape and may, alternatively, have a varied cross-sectional shape including conical, cylindrical, or a combination of multiple shapes. In one example, as shown in FIG. 3C, the first and second apertures may have a substantially cylindrical shape, and the third apertures may be formed by a series of cylinders of different diameters. For example, the third apertures may include three cylinders where the second cylinder is of a diameter smaller than the diameters of the other cylinders. These and numerous other variations can be used to modulate the flow of fluid through the apertures. As illustrated, the third apertures 375 may include an inward tapering conical frustum that is joined with a cylindrical region that serves as a choke point at a medial portion of the aperture. The choke point may transition to an outward tapering conical frustum, and then to a larger cylindrical region, however other aperture profiles may be utilized in various embodiments.

When all first and second apertures are of the same diameter, the flow of gas through the channels may not be uniform. As process gases flow into the processing chamber, the flow of gas may be such as to preferentially flow a greater volume of gas through certain channels. As such, certain of the apertures may be reduced in diameter from certain other apertures in order to redistribute the precursor flow as it is delivered into a first plasma region. The apertures may be selectively reduced in diameter due to their relative position, such as near a baffle, and as such, apertures located near the baffle may be reduced in diameter to reduce the flow of process gas through those apertures. In one example, as shown in FIG. 3A, where nine hexagonal rings of first apertures are located concentrically on the plates, certain rings of apertures may have some or all of the apertures reduced in diameter. For example, ring four may include a subset of first apertures that have a smaller diameter than the first apertures in the other rings. Alternatively, rings two through eight, two through seven, two through six, two through five, two through four, three through seven, three through six, three through five, four through seven, four through six, two and three, three and four, four and five, five and six, etc., or some other combination of rings may have reduced aperture diameters for some or all of the apertures located in those rings.

The dual-channel showerhead 300 may include a compressible gasket 385 that may be disposed between the upper plate 320 and the lower plate 325. For example, the gasket 385 may be generally disc-shaped and may be positioned such that the gasket 385 covers a top of the plenum 347. In a particular embodiment, the annular body 340 may define a ledge that is radially inward and/or positioned above the channels 306, 308 that supports a bottom surface of the gasket 385. The gasket 385 may define a plurality of apertures 390 that may each have an axis that aligns with the axes of a respective one of the first plurality of apertures 360 and the second plurality of apertures 365 to define a flow path through a thickness of the dual-channel showerhead 300. The gasket 385 may be formed from a compressible material that is chemically resistant. Suitable materials may include, but are not limited to, polytetrafluoroethylene (PTFE), thermoplastics such as Celazole® PBI, Semitron® ESD, and/or other compressible and chemically resistant materials that can withstand a plasma chemistry environment. The gasket 385 may have a thickness of between or about 0.10 inches and 0.50 inches, between or about 0.15 inches and 0.45 inches, between or about 0.20 inches and 0.40 inches, between or about 0.25 inches and 0.35 inches, between or about 0.275 inches and 0.325 inches, or between or about 0.2875 inches and 0.3125 inches. When the upper plate 320 is fastened to the annular body 340, the gasket 385 may seal the top of the plenum 347 to fluidly isolate the plenum 347 and third apertures 375 from the first apertures 360, second apertures 365, and apertures 390.

The annular body 340 may define an isolation channel 324. For example, the isolation channel 324 may be formed in a top surface of the annular body 340 that is radially outward of the channels 306, 308 such that a top of the isolation channel 324 is covered by upper plate 320 when the upper plate 320 is disposed within the first recess 303. In operation, the isolation channels may receive O-rings 326, for example, or other isolation devices. The O-rings 326 may provide a vacuum seal that separates the interior of the dual-channel showerhead 300 from the rest of the chamber.

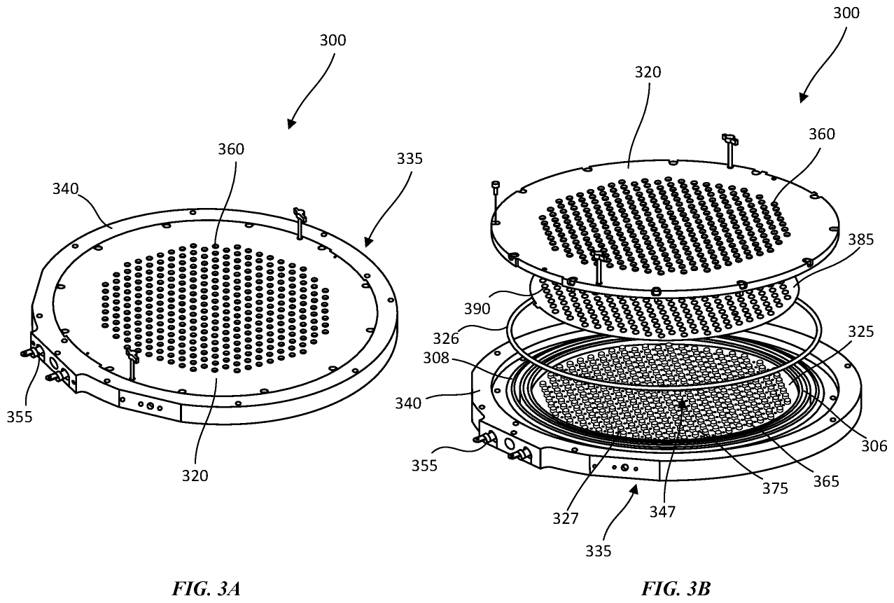

As noted above, the lower plate may be removably coupled with the annular body of the base in some embodiments. FIG. 4 illustrates a cross-sectional side elevation view of an embodiment of a dual-channel showerhead 400 that includes a removable lower plate 425. Dual-channel showerhead 400 may include any of the features or characteristics of dual-channel showerhead 300, and may be incorporated in any chamber in which a dual-channel showerhead may be used, including any chamber previously described. For example, dual-channel showerhead 400 may include a base 435 having an annular body 440. The dual-channel showerhead 400 may include an upper plate 420 defining a number of first apertures 460 and a lower plate 425 that defines second apertures 465 that are aligned with first apertures 460. The upper plate 420 may be removably fastened to the annular body 440. Lower plate 425 may also define third apertures 475 that are fluidly isolated from the first apertures 460 and second apertures 465. For example, the third apertures 475 may be fluidly coupled with a gas inlet 422 via one or more channels 406, 408 and/or a plenum 447. A gasket 485 may be positioned between the upper plate 420 and the lower plate 425 to fluidly isolate the plenum 447 and third apertures 475 from the first apertures 460, second apertures 465, and apertures 490 (which may be formed through the gasket 485).

The lower plate 425 may include a flange 423 that extends radially outward of an inner region of the lower plate 425 that defines the second apertures 465 and third apertures 475. The flange 423 may have a top surface that is depressed relative to a top surface of the first thickness of the lower plate 425 and that may be seated against a bottom surface of the annular body 440. For example, the annular body 440 may define a recess that receives the flange 423, with an upper surface of the recess contacting the upper surface of the flange 423 and an outer surface of the recess contacting an outer surface of the flange 423. A number of fasteners 424, such as screws, bolts, clamps, and/or other fastening mechanisms may be used to removably couple the lower plate 425 with the annular body 440. By making the lower plate 425 removable from the annular body 440, interior regions of the dual-channel showerhead 400 may be more easily cleaned without the various apertures restricting the flow of cleaning solution into the interior of the dual-channel showerhead 400. Additionally, the separation of the lower plate 425 from the annular body 440 may make it easier to machine complex features into the dual-channel showerhead 400.

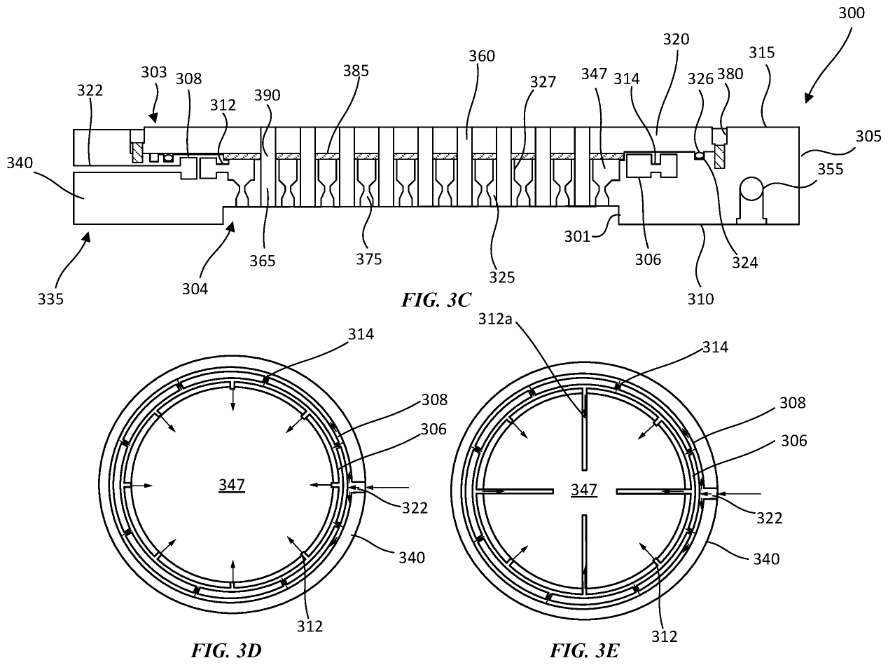

FIG. 5 illustrates a cross-sectional side elevation view of one embodiment of a dual-channel showerhead 500 according to the present invention. Dual-channel showerhead 500 may include any of the features or characteristics of dual-channel showerhead 300 or 400, and may be incorporated in any chamber in which a dual-channel showerhead may be used, including any chamber previously described. For example, dual-channel showerhead 500 may include a base 535 having an annular body 540. The dual-channel showerhead 500 may include an upper plate 520 defining a number of first apertures 560 and a lower plate 525 that defines second apertures 565 that are aligned with first apertures 560. Lower plate 525 may also define third apertures 575 that are fluidly isolated from the first apertures 560 and second apertures 565. For example, the third apertures 575 may be fluidly coupled with a gas inlet 522 via one or more channels 506, 508 and/or a plenum 547. Upper plate 520 and/or lower plate 525 may be removably fastened with the annular body 540 as described in relation to FIGS. 3A-3E and FIG. 4. A gasket 585 may be positioned between the upper plate 520 and the lower plate 525 to fluidly isolate the plenum 547 and third apertures 575 from the first apertures 560, second apertures 565, and apertures 590 (which may be formed through the gasket 585).

Gasket 585 may have a thickness that decreases as a radial distance from a center of the gasket 585 increases. In other words, the inner region of the gasket 585 may be thicker than a peripheral region of the gasket 585. This may help better seal the plenum 547 and third apertures 575 from the first apertures 560, second apertures 565, and apertures 590 when the upper plate 520 is fastened to the annular body 540. For example, the compressive force applied by fastening mechanisms 580 is greater proximate the fastening mechanisms 580 (e.g., near the peripheral regions of the upper plate 520). Thus, to better compress and seal the plenum 547, the gasket 585 may be thicker within the inner region of the gasket 585 to account for the lower degree of compression imparted by the medial portion of the upper plate 520. The transition between thicknesses of the inner and outer regions may be linear/angled, contoured, and/or stepped to create two or more regions of different thicknesses. As illustrated, the gasket 585 have a curved thickness transition that varies by radial distance. In some embodiments, the center of the gasket 585 may be at least or about 1.5× a thickness of a peripheral region, at least or about 2× the thickness of the peripheral region, at least or about 2.5× the thickness of the peripheral region, at least or about 3× the thickness of the peripheral region, at least or about 4× the thickness of the peripheral region, at least or about 5× the thickness of the peripheral region, at least or about 6× the thickness of the peripheral region, at least or about 7× the thickness of the peripheral region, at least or about 8× the thickness of the peripheral region, at least or about 9× the thickness of the peripheral region, at least or about 10× the thickness of the peripheral region, or greater.

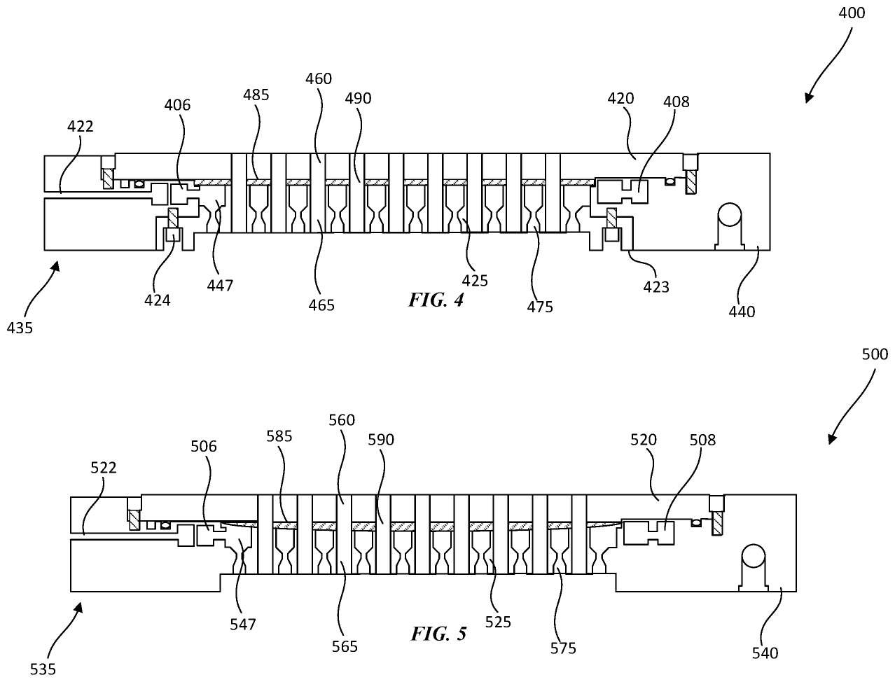

In some embodiments, the gasket may include cylindrical bodies and/or spigots positioned on a top and/or a bottom surface of the gasket. The spigots may provide more material thickness and/or thinner side walls, which may increase the amount of compression of the gasket to better seal the plenum from the first and second apertures. FIG. 6 illustrates a cross-sectional side elevation view of one embodiment of a dual-channel showerhead 600 according to the present invention. Dual-channel showerhead 600 may include any of the features or characteristics of dual-channel showerhead 300, 400, or 500, and may be incorporated in any chamber in which a dual-channel showerhead may be used, including any chamber previously described. For example, dual-channel showerhead 600 may include a base 635 having an annular body 640. The dual-channel showerhead 600 may include an upper plate 620 defining a number of first apertures 660 and a lower plate 625 that defines second apertures 665 that are aligned with first apertures 660. Lower plate 625 may also define third apertures 675 that are fluidly isolated from the first apertures 660 and second apertures 665. For example, the third apertures 675 may be fluidly coupled with a gas inlet 622 via one or more channels 606, 608 and/or a plenum 647. Upper plate 620 and/or lower plate 625 may be removably fastened with the annular body 640 as described in relation to FIGS. 3A-3E and FIG. 4. A gasket 685 may be positioned between the upper plate 620 and the lower plate 625 to fluidly isolate the plenum 647 and third apertures 675 from the first apertures 660, second apertures 665, and apertures 690 (which may be formed through the gasket 685).

A bottom surface of gasket 685 may include a number of cylindrical bodies or spigots 687 that extend downward from the bottom surface. For example, a spigot 687 may extend downward and surround each of the apertures 690 formed through a thickness of the gasket 685 such that the spigots 687 partially define the fluid path formed by the first and second apertures through the thickness of the dual-channel showerhead 600. In some embodiments, a height of each spigot 687 may be the same, while in other embodiments the heights of spigots near the center of the gasket 685 may be greater than heights of spigots 687 proximate the peripheral edge of the gasket 685. The transition between spigots 687 of different heights may be done linearly, with a contour, and/or in stepped fashion. In embodiments with a linear and/or contoured transition, bottom surfaces of each individual spigot 687 may have variable heights. Stepped transitions may include steps that include a single row of spigots 687 and/or that include multiple rows of spigots 687. In some embodiments, the height of each spigot 687 may be between or about 0.05 inches and 0.375 inches, between or about 0.1 inches and 0.35 inches, between or about 0.15 inches and 0.3 inches, or between or about 0.2 inches and 0.25 inches. While illustrated with spigots 687 extending downward from the bottom surface of gasket 685, in some embodiments the gasket 685 may be inverted such that the spigots 687 extend upward from an upper surface of the gasket 685. The modulus of elasticity of the gasket 685 may be selected to prevent significant lateral deformation of the spigots 687 as the spigots 687 are compressed by the upper plate 620.

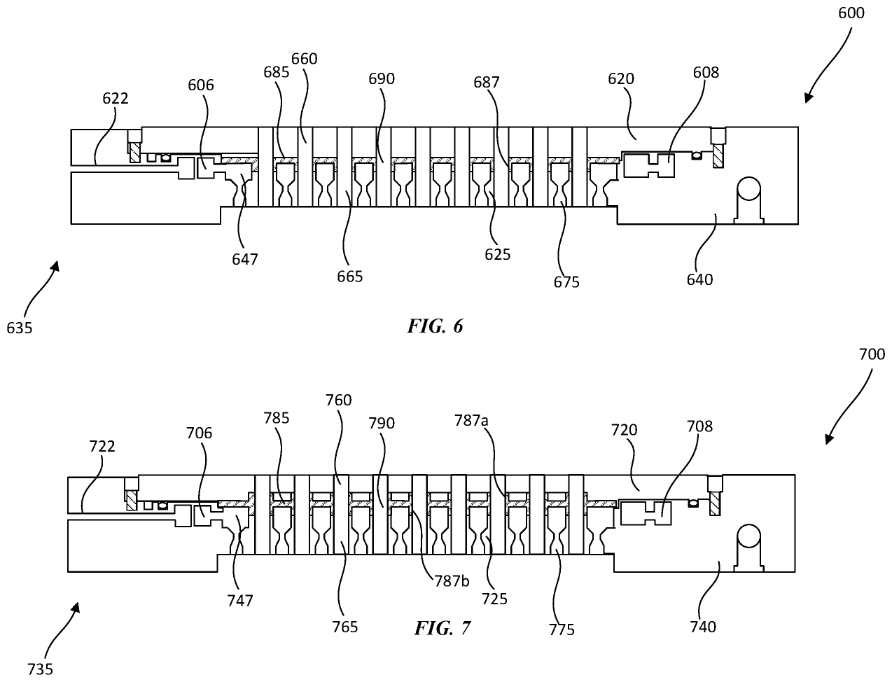

FIG. 7 illustrates a cross-sectional side elevation view of one embodiment of a dual-channel showerhead 700 according to the present invention. Dual-channel showerhead 700 may include any of the features or characteristics of dual-channel showerhead 300, 400, 500, or 600, and may be incorporated in any chamber in which a dual-channel showerhead may be used, including any chamber previously described. For example, dual-channel showerhead 700 may include a base 735 having an annular body 740. The dual-channel showerhead 700 may include an upper plate 720 defining a number of first apertures 760 and a lower plate 725 that defines second apertures 765 that are aligned with first apertures 760. Lower plate 725 may also define third apertures 775 that are fluidly isolated from the first apertures 760 and second apertures 765. For example, the third apertures 775 may be fluidly coupled with a gas inlet 722 via one or more channels 706, 708 and/or a plenum 747. Upper plate 720 and/or lower plate 725 may be removably fastened with the annular body 740 as described in relation to FIGS. 3A-3E and FIG. 4. A gasket 785 may be positioned between the upper plate 720 and the lower plate 725 to fluidly isolate the plenum 747 and third apertures 775 from the first apertures 760, second apertures 765, and apertures 790 (which may be formed through the gasket 785).

Both a top surface and a bottom surface of gasket 785 may include a number of cylindrical bodies or spigots 787 that extend upward or downward from the respective surface of the gasket 785. For example, a spigot 787a may extend upward from the upper surface and surround each of the apertures 790 formed through a thickness of the gasket 785, while a spigot 787b may extend downward from the bottom surface and surround each of the apertures 790 formed through a thickness of the gasket 785 such that the spigots 787 partially define the fluid path formed by the first and second apertures through the thickness of the dual-channel showerhead 700. In some embodiments, a height of each spigot 787 may be the same, while in other embodiments the heights of spigots near the center of the gasket 785 may be greater than heights of spigots 787 proximate the peripheral edge of the gasket 785. In some embodiments, only the heights of spigots 787a or 787b may vary while the spigots on the other surface of the gasket 785 have constant heights across the surface area of the gasket 785. The transition between spigots 787 of different heights may be done linearly, with a contour, and/or in stepped fashion. In embodiments with a linear and/or contoured transition, top or bottom surfaces of each individual spigot 787 may have variable heights. Stepped transitions may include steps that include a single row of spigots 787 and/or that include multiple rows of spigots 787. In some embodiments, the height of each spigot 787 may be between or about 0.05 inches and 0.375 inches, between or about 0.1 inches and 0.35 inches, between or about 0.15 inches and 0.3 inches, or between or about 0.2 inches and 0.25 inches. In some embodiments, a height of spigots 787a and spigots 787b may be the same, while in other embodiments spigots 787a may be shorter or taller than spigots 787b.

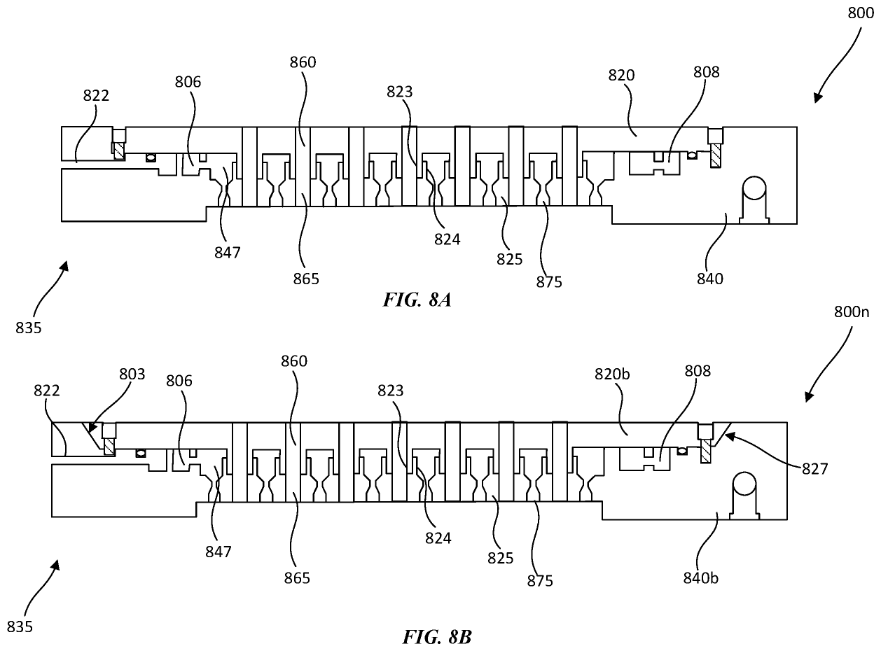

In some embodiments, dual-channel showerheads may omit the use of a compressible gasket altogether. FIG. 8A illustrates a cross-sectional side elevation view of one embodiment of a dual-channel showerhead 800 according to the present invention. Dual-channel showerhead 800 may include any of the features or characteristics of dual-channel showerhead 300, 400, 500, 600, or 700, and may be incorporated in any chamber in which a dual-channel showerhead may be used, including any chamber previously described. For example, dual-channel showerhead 800 may include a base 835 having an annular body 840. The dual-channel showerhead 800 may include an upper plate 820 defining a number of first apertures 860 and a lower plate 825 that defines second apertures 865 that are aligned with first apertures 860. Lower plate 825 may also define third apertures 875 that are fluidly isolated from the first apertures 860 and second apertures 865. For example, the third apertures 875 may be fluidly coupled with a gas inlet 822 via one or more channels 806, 808 and/or a plenum 847. Upper plate 820 and/or lower plate 825 may be removably fastened with the annular body 840 as described in relation to FIGS. 3A-3E and FIG. 4.

The first apertures 860 may extend beyond a bottom surface of the upper plate 820 thereby forming a number of raised cylindrical bodies or spigots 823. In between each spigot 823 may be a gap. The lower plate 825 may include a number of receptor cups 824 that extend upward from an upper surface of the lower plate 825. The receptor cups 824 may be axially aligned with the spigots 823 and may have inner diameters that are sized to substantially match an outer diameter of each spigot 823 such that each spigot 823 may nest within and/or otherwise interlock with a respective one of the receptor cups 824 with inner walls of the receptor cup 824 touching or nearly touching the outer walls of the spigot 823. Due to the close proximity of the walls of the receptor cups 824 and spigots 823, no gasket may be needed as the absence or narrowness of a gap formed between the walls may create an area of higher resistance that will prevent process gases from flowing within the gaps when under normal operating pressures/conditions.

FIG. 8B illustrates a cross-sectional side elevation view of one embodiment of a dual-channel showerhead 800b according to the present invention. Dual-channel showerhead 800b may be identical to dual-channel showerhead 800, except that at least a portion of an upper recess 803 formed in the annular body 840b in dual-channel showerhead 800b may be defined by a tapered wall (rather than a vertical wall as provided in dual-channel showerhead 800). Similarly, a bottom surface of upper plate 820b may have a tapered peripheral edge 827, which may have a degree of taper that matches the degree of taper of the upper recess 803. These tapered surfaces may enable the upper plate 820b to be self-aligning within the annular body 840 prior to the components being fastened together. The large tapered interface formed between the components may enable the components to be readily aligned without the use of other smaller alignment mechanisms, such as pin and receptacle connections, which may be easily damaged as a user attempts to align the alignment features during assembly of the dual-channel showerhead.

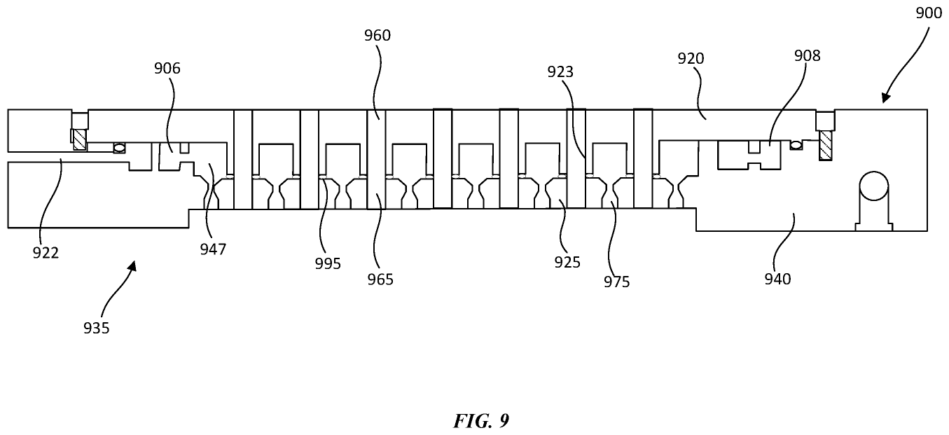

FIG. 9 illustrates a cross-sectional side elevation view of one embodiment of a dual-channel showerhead 900 according to the present invention. Dual-channel showerhead 900 may include any of the features or characteristics of dual-channel showerhead 300, 400, 500, 600, 700, or 800, and may be incorporated in any chamber in which a dual-channel showerhead may be used, including any chamber previously described. For example, dual-channel showerhead 900 may include a base 935 having an annular body 940. The dual-channel showerhead 900 may include an upper plate 920 defining a number of first apertures 960 and a lower plate 925 that defines second apertures 965 that are aligned with first apertures 960. Lower plate 925 may also define third apertures 975 that are fluidly isolated from the first apertures 960 and second apertures 965. For example, the third apertures 975 may be fluidly coupled with a gas inlet 922 via one or more channels 906, 908 and/or a plenum 947. Upper plate 920 and/or lower plate 925 may be removably fastened with the annular body 940 as described in relation to FIGS. 3A-3E and FIG. 4.

The first apertures 960 may extend beyond a bottom surface of the upper plate 920 thereby forming a number of raised cylindrical bodies or spigots 923. In between each spigot 923 may be a gap. The dual-channel showerhead 900 may include a number of seals 995 that are positioned at an interface between a bottom end of a respective one of the plurality of spigots 923 and a top surface of the lower plate 925. For example, the seals 995 may be generally annular in shape and be sized to be approximately a same diameter of each of the spigots 923. The seals 995 may be formed from a compressible material that is chemically resistant. In some embodiments, the seals 995 may include elastomers, thermoplastic materials, and/or other chemically resistant materials. When the upper plate 920 is fastened to the annular body 940, the seals 995 may be compressed to seal the plenum 947 and third apertures 975 from the first and second apertures.

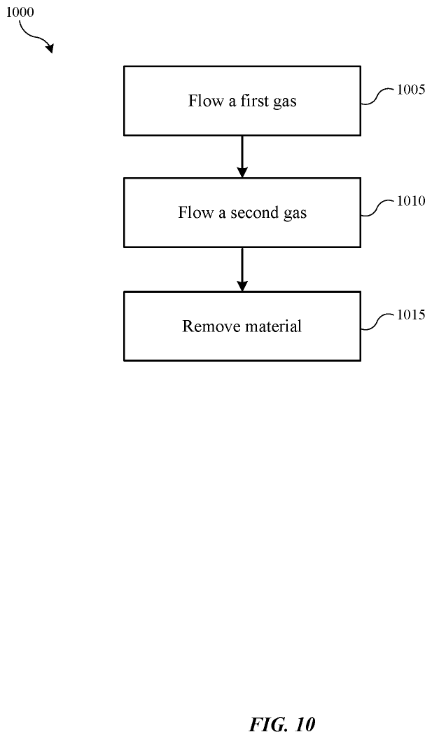

FIG. 10 shows operations of an exemplary method 1000 of semiconductor processing according to some embodiments of the present technology. The method 1000 may be performed in a variety of processing chambers, including processing system 200 described above, which may include dual-channel showerheads that include removable upper and/or lower plates according to embodiments of the present technology, such as dual-channel showerheads 300, 400, 500, 600, 700, 800, and 900. Method 1000 may include a number of optional operations, which may or may not be specifically associated with some embodiments of methods according to the present technology.

Method 1000 may include a processing method that may include operations for forming a hardmask film or other deposition and/or etch operations. The method may include optional operations prior to initiation of method 1000, or the method may include additional operations. For example, method 1000 may include operations performed in different orders than illustrated. In some embodiments, method 1000 may include flowing a first gas into a processing chamber through a first plurality of apertures formed in an upper plate of a showerhead and a second plurality of apertures formed in a lower plate of the showerhead at operation 505. For example, the first gas may include a plasma generating gas such as, but not limited to, CF4, NH3, NF3, Ar, He, H2O, H2, O2. A second gas may be flowed into the processing chamber through a third plurality of apertures formed in the lower plate via a gas inlet formed in a base of the showerhead at operation 1010. For example, the second gas may be introduced into a plenum that is fluidly coupled with each of the third plurality of apertures via a recursive flow path that extends between the gas inlet and the plenum. The second gas may include a gas/precursor mixture and may depend on the operation being performed. For example, the second gas may include deposition compounds (e.g., Si-containing compounds) for deposition processes and etchants for etch processes. The second gas may be flowed into the processing region via a second plurality of apertures of a dual-channel showerhead assembly. A compressible gasket and/or individual aperture seals may be disposed between the upper plate and the lower plate to fluidly isolate the first and second apertures from the third apertures. In other embodiments, the upper and lower plates may include interlocking features that fluidly isolate the first and second apertures from the third apertures. The method 1000 may include removing an amount of material on a substrate positioned within the processing chamber at operation 1015.

In the preceding description, for the purposes of explanation, numerous details have been set forth in order to provide an understanding of various embodiments of the present invention. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the disclosed embodiments. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the smallest fraction of the unit of the lower limit, unless the context clearly dictates otherwise, between the upper and lower limits of that range is also specifically disclosed. Each smaller range between any stated value or intervening value in a stated range and any other stated or intervening value in that stated range is encompassed. The upper and lower limits of those smaller ranges may independently be included or excluded in the range, and each range where either, neither, or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or steps, but they do not preclude the presence or addition of one or more other features, integers, components, steps, acts, or groups.

What is claimed is:

1. A dual-channel showerhead, comprising:
an upper plate that defines a first plurality of apertures;
a base comprising a lower plate, the lower plate defining a second plurality of apertures and a third plurality of apertures, wherein:
each of the first plurality of apertures is fluidly coupled with a respective one of the second plurality of apertures to define a fluid path extending from a top surface of the showerhead through a bottom surface of the showerhead;
the base defines a gas inlet that is fluidly coupled with the third plurality of apertures; and
the base is detachably coupled with the upper plate using one or more fastening mechanisms; and
a compressible gasket that fluidly isolates the first plurality of apertures and the second plurality of apertures from the third plurality of apertures, the compressible gasket being positioned between the upper plate and the lower plate.

2. The dual-channel showerhead of claim 1, wherein:
each of the third plurality of apertures is fluidly isolated from the first plurality of apertures and the second plurality of apertures.

3. The dual-channel showerhead of claim 1, wherein:
the base defines a plenum that fluidly couples the gas inlet with each of the third plurality of apertures.

4. The dual-channel showerhead of claim 3, wherein:
the base defines a recursive flow path that fluidly couples the gas inlet with the plenum.

5. The dual-channel showerhead of claim 1, wherein:
the gasket comprises a body characterized by a top surface and a bottom surface;
one or both of the top surface and the bottom surface comprise a plurality of spigots that protrude outward from the body of the gasket; and
each of the plurality of spigots is vertically aligned with a respective one of the first plurality of apertures.

6. The dual-channel showerhead of claim 1, wherein:
the gasket comprises polytetrafluoroethylene (PTFE).

7. The dual-channel showerhead of claim 1, wherein:
one or both of a top surface of the gasket and a bottom surface of the gasket comprise a plurality of spigots that protrude outward from a body of the gasket; and
the gasket has a thickness that decreases as a radial distance from a center of the gasket increases.

8. The dual-channel showerhead of claim 1, wherein:
the lower plate is detachably coupled with the base using one or more fasteners.

9. The dual-channel showerhead of claim 1, wherein:
the gasket has a thickness that decreases as a radial distance from a center of the gasket increases.

10. A dual-channel showerhead, comprising:
an upper plate that defines a first plurality of apertures; and
a base comprising a lower plate, the lower plate defining a second plurality of apertures and a third plurality of apertures, wherein:
each of the first plurality of apertures is fluidly coupled with a respective one of the second plurality of apertures to define a fluid path extend from a top surface of the showerhead through a bottom surface of the showerhead;
the base defines a gas inlet that is fluidly coupled with the third plurality of apertures; and
the base is detachably coupled with the upper plate using one or more fastening mechanisms.

11. The dual-channel showerhead of claim 10, wherein:
the base defines a seat that receives the upper plate.

12. The dual-channel showerhead of claim 11, wherein:
an outer region of the seat tapers upward toward a periphery of the seat;
a peripheral edge of a bottom surface of the upper plate is tapered; and
a degree of taper of the outer region of the seat matches a degree of taper of the peripheral edge of the bottom surface of the seat.

13. The dual-channel showerhead of claim 10, wherein:
a bottom surface of the upper plate comprises a plurality of spigots that extend downward from the bottom surface, each of the plurality of spigots defining at least a portion of a respective one of the first plurality of apertures; and
the showerhead comprises a plurality of seals, each of the plurality of seals being positioned at an interface between a bottom end of a respective one of the plurality of spigots and a top surface of the lower plate.

14. The dual-channel showerhead of claim 10, wherein:
a bottom surface of the upper plate comprises a plurality of spigots that extend downward from the bottom surface, each of the plurality of spigots defining at least a portion of a respective one of the first plurality of apertures; and
a top surface of the lower plate comprises a plurality of receptor cups extending upward from the top surface, each of the plurality of receptor cups receiving a respective one of the plurality of spigots.

15. The dual-channel showerhead of claim 10, wherein:
each of the first plurality of apertures and each of the second plurality of apertures are generally cylindrical.

16. The dual-channel showerhead of claim 10, wherein:
an inner wall of each of the third plurality of apertures tapers inward to a choke point disposed within a medial portion of the respective aperture.

17. The dual-channel showerhead of claim 10, wherein:
the base comprises a heating coil extending at least partially about a circumference of the base.

18. A method of processing a substrate, comprising:
flowing a first gas into a processing chamber through a first plurality of apertures formed in an upper plate of a showerhead and a second plurality of apertures formed in a lower plate of the showerhead;
flowing a second gas into the processing chamber through a third plurality of apertures formed in the lower plate via a gas inlet formed in a base of the showerhead, wherein:
the upper plate is detachably coupled with the base using one or more fastening mechanisms; and
removing an amount of material from a substrate positioned within the processing chamber.

19. The method of processing a substrate of claim 18, wherein:
the showerhead comprises a compressible gasket positioned between the upper plate and the lower plate.

20. The method of processing a substrate of claim 18, wherein:
flowing the second gas comprises introducing the precursor into a plenum that is fluidly coupled with each of the third plurality of apertures via a recursive flow path that extends between the gas inlet and the plenum.
